(19) United States
(12) Patent Application Publication
(10) Pub. No.: US 2026/0221966 A1
(43) Pub. Date: Jul. 30, 2026

(54) POWER SUPPLY APPARATUS, MANAGEMENT APPARATUS, AND DRIVING CIRCUIT

(71) Applicant: FUJI ELECTRIC CO., LTD., Kanagawa (JP)

(72) Inventor: Sho NAKAGAWA, Matsumoto-city (JP)

(21) Appl. No.: 19/399,405

(22) Filed: Nov. 24, 2025

(30) Foreign Application Priority Data
Jan. 28, 2025 (JP) 2025-012407

(51) Int. Cl. H03K 17/18; H03K 17/0812; H03K 17/08

(52) U.S. Cl. CPC H03K 17/18; H03K 17/08122; H03K 2017/0806; H03K 2217/0027; H03K 2217/0063; H03K 2217/0081

(57) ABSTRACT

A driving circuit includes a state terminal which outputs a state signal indicating a state of the driving circuit; a current-sensing terminal which outputs a sensing signal of a current flowing through a power device; and a state-signal generation unit connected to the state terminal, which, based on receiving driving power from a second power source different from a first power source connected to a high potential terminal of the driving circuit, generates the state signal, and a management apparatus distinguishes individually, based on the state signal and the sensing signal, whether or not the state of the driving circuit is in a normal state; whether or not the state of the driving circuit is in a loss-of-power state; and whether or not the state of the driving circuit is in a load-open state.

The contents of the following patent application (s) are incorporated herein by reference:

NO. 2025-012407 filed in JP on January 28, 2025.

### BACKGROUND

### Technical Field

The present invention relates to a power supply apparatus, a management apparatus, and a driving circuit.

### Related Art

Patent document 1 discloses a semiconductor apparatus "that supplies electrical power to a load." (Paragraph 0001, FIG. 1, for example). Patent document 2 discloses an electronic control apparatus that includes "a regeneration-current-failure detection unit configured to detect a sticking failure of at least one electromagnetic valve." (Claim 1, for example).

Patent Document 1: Japanese Patent Application Publication No. 2024-144186

Patent Document 2: Japanese Patent Application Publication No. 2023-034058

### BRIEF DESCRIPTION OF THE DRAWINGS

FIG. 1 illustrates an example of a power supply apparatus 400 according to one embodiment of the present invention.

FIG. 2 illustrates an exemplary configuration of a driving circuit 100.

FIG. 3 illustrates an example of combinations of respective states of the driving circuit 100 and logical values of an input signal IN, a state signal ST, a sensing signal SNS, and an output signal OUT.

FIG. 4 illustrates another example of combinations of the respective states of the driving circuit 100 and, the logical values of the respective signals.

FIG. 5 illustrates another example of the power supply apparatus 400.

FIG. 6 illustrates another exemplary configuration of the driving circuit 100.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solving means of the invention.

When expressions such as “equal” or “same” are used in the present specification, they may include errors resulting from manufacturing variations or the like, in addition to being strictly equal. Such errors are, for example, ±5% or less. Also, when expressions relating to angles, such as "vertical", "parallel", are used, they may include errors resulting from manufacturing variations or the like, in addition to being strictly 90 degrees, 180 degrees or the like. Such errors are, for example, ± 5 degrees or less.

When expressions such as “above”, “below”, “upper”, or “lower” are used in the present specification, these directions indicate relative directions. For example, these directions do not indicate a direction of gravitational force and do not indicate a direction when implementing an apparatus.

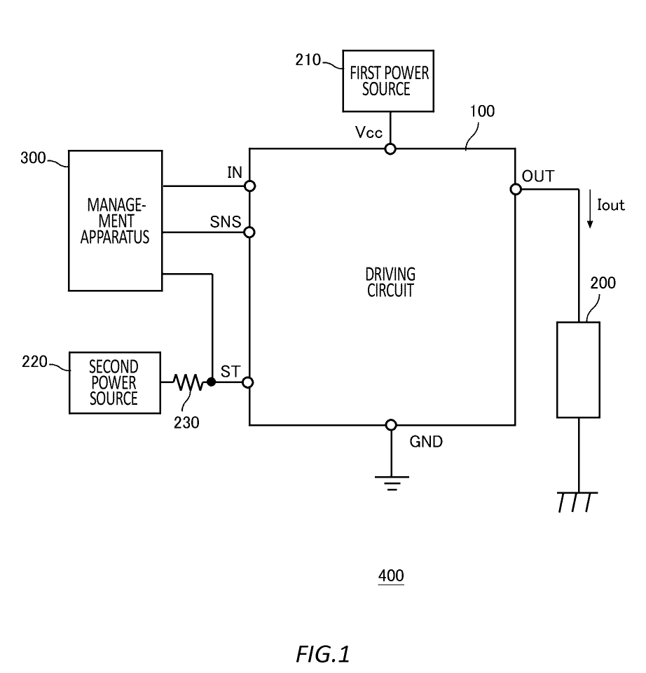

FIG. 1 illustrates an example of a power supply apparatus 400 according to one embodiment of the present invention. The power supply apparatus 400 supplies electrical power to a load 200. For example, the power supply apparatus 400 and the load 200 are equipped in a vehicle, but not limited thereto. As an example, the load 200 is a motor of an electric car, but not limited thereto.

The power supply apparatus 400 includes a driving circuit 100 and a management apparatus 300. The driving circuit 100 supplies electrical power to the load 200. The driving circuit 100 may be a semiconductor chip provided on one semiconductor substrate. A part of a configuration of the driving circuit 100 described herein may be provided outside the semiconductor chip.

The management apparatus 300 manages the driving circuit 100. The management apparatus 300 of the present example generates an input signal IN that controls an operation of the driving circuit 100.

The driving circuit 100 of the present example is a semiconductor chip which has an input terminal IN, an output terminal OUT, a high potential terminal Vcc, a low potential terminal GND, a state terminal ST, and a sense terminal SNS. A predetermined high potential Vcc is applied to the high potential terminal Vcc. A low potential GND, which is lower than the high potential Vcc, is applied to the low potential terminal GND. The low potential GND of the present example is a ground potential. Respective circuits of the driving circuit 100 may receive electrical power from a power source connected to the high potential terminal Vcc. A first power source 210 is connected to the high potential terminal Vcc of the present example.

The driving circuit 100 operates according to the input signal IN that is input into the input terminal IN to supply electrical power to the load 200 connected to the output terminal OUT. The input signal IN of the present example may be a signal of a binary logical value that indicates whether or not to supply electrical power to the load 200. The driving circuit 100 may have a power device that switches whether or not to supply electrical power to the load 200. The power device is, for example, a switching element such as an IGBT or a MOSFET. The driving circuit 100 drives, based on the input signal IN, the power device. The driving circuit 100 of the present example controls, based on the input signal IN, the on/off of the power device.

The state terminal ST outputs a state signal ST indicating a state of the driving circuit 100. The state of the driving circuit 100 includes at least a normal state, a loss-of-power state, and a load-open state. The normal state is a state where the power device transitions, based on the input signal IN, between an ON state and an OFF state. That is, the normal state is a state where the respective circuits operate normally, wherein whether or not to supply electrical power to the load 200 is switched according to the input signal IN. The loss-of-power state is a state where electrical power from the first power source 210 is not supplied to the driving circuit 100. The loss-of-power state includes a state where the first power source 210 is not connected to the high potential terminal Vcc, a state where a transmission path that transmits electrical power from the first power source 210 is disconnected, and the like. The load-open state is a state where the load 200 is not connected to the power device of the driving circuit 100. The load-open state includes a state where the load 200 is not connected to the output terminal OUT, a state where a transmission path that transmits electrical power from the driving circuit 100 to the load 200 is disconnected, and the like.

A second power source 220 different from the first power source 210 may be connected to the state terminal ST. The second power source 220 of the present example is connected to the state terminal ST via a resistor 230. The driving circuit 100 may switch, according to the state of the driving circuit 100, whether a potential at the state terminal ST is a potential output by the second power source 220, or a potential inside the driving circuit 100 (for example, the low potential GND).

The state of the driving circuit 100 may further include at least one of an overheat state, an overcurrent state, a low-voltage state, or an input-terminal-open state. The overheat state is a state where a temperature of the driving circuit 100 is higher than a set temperature that is set in advance. The overcurrent state is a state where a current flowing through the power device of the driving circuit 100 is higher than an upper limit value that is set in advance. The low-voltage state is a state where a voltage value of a predetermined node inside the driving circuit 100, e.g., the high potential terminal Vcc, is lower than a lower limit value that is set in advance. The input-terminal-open state is a state where an input circuit, such as the management apparatus 300, is not connected to the input terminal IN.

The current-sensing terminal SNS outputs a sensing signal SNS of a current flowing through the power device of the driving circuit 100. The sensing signal SNS may be a signal indicating a magnitude of the current. The sensing signal SNS may be a voltage signal having a magnitude proportional to the magnitude of the current.

The management apparatus 300 individually distinguishes, based on the state signal ST and the sensing signal SNS, whether or not the state of the driving circuit 100 is the normal state, whether or not the state of the driving circuit 100 is the loss-of-power state, and whether or not the state of the driving circuit 100 is the load-open state. Each of the state signal ST and the sensing signal SNS may be a binary signal. The state signal ST may indicate a first logical value in one or more particular states, and indicate a second logical value in another state. The sensing signal SNS may be a signal indicating whether or not a magnitude of the current flowing through the power device is higher than a predetermined reference value. In this case, there are four possible combinations of a logical value of the state signal ST and a logical value of the sensing signal SNS. Which state of the driving circuit 100 each of the four possible combinations corresponds to may be set in advance in the management apparatus 300.

The management apparatus 300 may distinguish, based on the state signal ST and the sensing signal SNS, whether or not the driving circuit 100 is in an abnormal state, in addition to the three states, i.e., the normal state, the loss-of-power state, and the load-open state. The abnormal state may be at least one of the overheat state, the overcurrent state, the low-voltage state, or the input-terminal-open state as described above. The management apparatus 300 may distinguish, as the abnormal state, several or all of the overheat state, the overcurrent state, the low-voltage state, and the input-terminal-open state, collectively.

The management apparatus 300 may control, according to the state of the driving circuit 100 distinguished by the management apparatus 300, the driving circuit 100. For example, the management apparatus 300 may control, when the state of the driving circuit 100 is a state other than the normal state, the logical value of the input signal IN such that the power device of the driving circuit 100 is kept in the OFF state. This control allows for preventing the overcurrent state from continuing, for example.

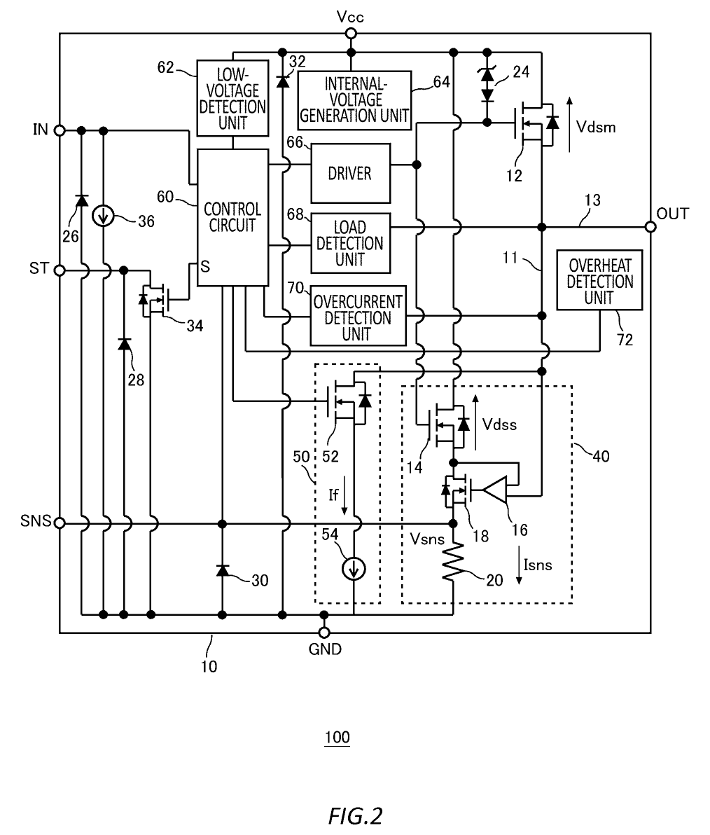

FIG. 2 illustrates an exemplary configuration of the driving circuit 100. The driving circuit 100 may be provided on a semiconductor substrate 10. The semiconductor substrate 10 may be a silicon substrate, or may be a compound semiconductor substrate of SiC, GaN, or the like.

The driving circuit 100 may include a control circuit 60, a driver 66, a power device 12, and an output wiring 13. The power device 12 of the present example is provided between the high potential terminal Vcc and the output terminal OUT, and switches whether or not electrical power is supplied from the high potential terminal Vcc to the output terminal OUT. A source terminal of the power device 12 and the output terminal OUT are connected by the output wiring 13. The output wiring 13 may include a point-to-point construction of wires or the like. The power device 12 is, for example, a power MOSFET, but may also be another type of power semiconductor such as an IGBT.

The control circuit 60 outputs, according to the logical value of the input signal IN, a control pattern for controlling the on/off of the power device 12. The control pattern may be a binary signal having H logic and L logic. The driver 66 inputs a control signal having a waveform which corresponds to a logical value pattern of the control pattern into a control terminal, such as a gate terminal of the power device 12. Thereby, whether or not electrical power is supplied to the load 200 is switched according to the input signal IN.

The driving circuit 100 may further include at least one of a low-voltage detection unit 62, an internal-voltage generation unit 64, a driver 66, a load detection unit 68, an overcurrent detection unit 70, or an overheat detection unit 72. The internal-voltage generation unit 64 generates, based on the high potential Vcc, an internal voltage. The internal voltage is used as a power source voltage of each configuration inside the driving circuit 100, such as the low-voltage detection unit 62, the control circuit 60, the driver 66, the load detection unit 68, the overcurrent detection unit 70, and the overheat detection unit 72. The internal-voltage generation unit 64 may include a voltage regulator.

The low-voltage detection unit 62 detects whether or not the high potential Vcc at the high potential terminal Vcc gets lower than a lower limit value that is set in advance. The low-voltage detection unit 62 informs the control circuit 60 of a detection result. The control circuit 60 distinguishes, based on the information from the low-voltage detection unit 62, whether or not the driving circuit 100 is in the low-voltage state.

The load detection unit 68 detects whether or not the load 200 is connected to the output terminal OUT. The load detection unit 68 may detect at least one of an output voltage Vout or an output current Iout, which are applied to the output terminal OUT, or may detect an impedance component connected to the output terminal OUT. For example, the load detection unit 68 may determine, if the output current Iout when the power device 12 is in the ON state is lower than a reference value, that the load 200 is not connected. The load detection unit 68 informs the control circuit 60 of a detection result. The control circuit 60 distinguishes, based on the information from the load detection unit 68, whether or not the driving circuit 100 is in the load-open state.

The overcurrent detection unit 70 detects whether or not the current flowing through the power device 12 gets higher than an upper limit value that is set in advance. The overcurrent detection unit 70 may determine, based on a voltage of the source terminal of the power device 12, whether or not an overcurrent is flowing through the power device 12. The overcurrent detection unit 70 informs the control circuit 60 of a detection result. The control circuit 60 distinguishes, based on the information from the overcurrent detection unit 70, whether or not the driving circuit 100 is in the overcurrent state.

The overheat detection unit 72 detects whether or not the temperature of the driving circuit 100 gets higher than a set temperature that is set in advance. The overheat detection unit 72 may include a temperature detection element, such as a p-n junction diode. The overheat detection unit 72 informs the control circuit 60 of a detection result. The control circuit 60 distinguishes, based on the information from the overheat detection unit 72, whether or not the driving circuit 100 is in the overheat state.

The driving circuit 100 of the present example includes a state-signal generation unit 34. The state-signal generation unit 34 is connected to the state terminal ST and receives the driving power from the second power source 220 (see FIG. 1). The state-signal generation unit 34 may include a transistor element having a drain terminal connected to the second power source 220 and a gate terminal to which the state signal ST is applied from the control circuit 60. The low potential terminal GND may be connected to a source terminal of the transistor element. The transistor element switches whether or not the state terminal ST and the low potential terminal GND are connected.

The control circuit 60 controls the state-signal generation unit 34. A state signal S is applied to the gate terminal of the state-signal generation unit 34 from the control circuit 60. The state-signal generation unit 34 generates, based on the state signal S, a state signal ST.

The state signal S of the present example is a signal indicating H logic when at least one of the abnormal states, i.e., the overheat state, the overcurrent state, the low-voltage state, or the input-terminal-open state is detected. When no abnormal states are detected, the state signal S may make a transition, according to the input signal IN, of its logical value.

When the state signal S is H logic, the state-signal generation unit 34 turns to an ON state, and the state signal ST becomes at the low potential GND. When the state signal S is L logic, the state-signal generation unit 34 turns to an OFF state, and the state signal ST becomes at a high potential (for example, an output potential of the second power source 220). This configuration allows for generating the state signal ST indicating whether or not the driving circuit 100 is in an abnormal state.

The control circuit 60 directly or indirectly receives source power from the first power source 210. In the present example, the internal-voltage generation unit 64 generates source power, depending on electrical power supplied by the first power source 210. In the loss-of-power state, the power source voltage is not applied to the control circuit 60, and the control circuit 60 does not operate. In this case, the state signal S is L logic. Thus, in the loss-of-power state, the state-signal generation unit 34 turns to the OFF state, and the state signal ST becomes at the high potential.

The driving circuit 100 may include a current-sensing circuit 40. The current-sensing circuit 40 senses a magnitude of the current flowing through the power device 12. The current-sensing circuit 40 of the present example includes a current-sensing element 14, an amplifier 16, a MOSFET 18, and a sense resistor 20.

A sense current Isns depending on the output current Iout flowing through the power device 12 flows through the current-sensing element 14. The current-sensing element 14 is a power semiconductor that is provided in parallel with the power device 12, and has a similar structure to the power device 12. In the example of FIG. 2, the current-sensing element 14 and the power device 12 are both MOSFETs. The control circuit 60 and the driver 66 cause the power device 12 and the current-sensing element 14 to transition to the ON state in synchronization and transition to the OFF state in synchronization.

The sense current Isns, which corresponds to a current obtained by multiplying the output current Iout by a predetermined sense ratio, flows through the current-sensing element 14. The sense ratio is determined by an area ratio of regions where current flows in the current-sensing element 14 and in the power device 12, an ON-resistance ratio of the current-sensing element 14 and the power device 12, or the like. The sense current Isns is lower than the output current Iout. That is, the sense ratio is less than 1. For example, the sense current Isns may be 1/ 100 or less, or 1/ 1000 or less of the output current Iout.

A sense resistor 20 is provided between the current-sensing element 14 and the low potential terminal GND. The sense resistor 20 causes a voltage drop which corresponds to a sense voltage Vsns obtained by multiplying the sense current Isns by the resistance value. The sense current Isns can be calculated from the sense voltage Vsns and the resistance value of the sense resistor 20. The sense terminal SNS may output the sense voltage Vsns to the outside. Since a sense ratio of the sense current Isns and the current-sensing element 14 is known, the output current Iout can be calculated from the sense current Isns. The resistance value of the sense resistor 20 may be variable or fixed.

A first sense wiring 11 is used to make equal a potential (in the present example, a source potential) output by the power device 12 and a potential (in the present example, a source potential) output by the current-sensing element 14. This allows for causing a drain-to-source voltage Vdsm of the power device 12 and a drain-to-source voltage Vdss of the current-sensing element 14 to match, and thus mitigating a variation in the sense ratio caused by a variation in the output voltage.

In the present example, the MOSFET 18 is provided between the current-sensing element 14 and the sense resistor 20. Also, the amplifier 16 adjusts a voltage applied to a gate terminal of the MOSFET 18, such that a voltage applied by the first sense wiring 11 (for example, the source potential of the power device 12) and the source potential of the current-sensing element 14 are equal. This configuration allows for making equal the potential (in the present example, the source potential) output by the power device 12 and the potential (in the present example, the source potential) output by the current-sensing element 14.

The driving circuit 100 may include a defined current unit 50 that controls, when the driving circuit 100 is in a predetermined state, the current flowing through the power device 12 to be at a set value that is set in advance. The predetermined state of the present example is the load-open state. The predetermined state may be another state.

The defined current unit 50 includes a MOSFET 52 and a current source 54. The current source 54 generates a set current If corresponding to the set value If as described above. The MOSFET 52 switches whether or not the source terminal of the power device 12 is connected to the current source 54. The control circuit 60 controls, when the driving circuit 100 is in a predetermined state, the MOSFET 52 to be in the ON state to connect the current source 54 to the source terminal of the power device 12. Thereby, the current flowing through the power device 12 is controlled to be at a set current If. In this case, the sense current Isns, which the current-sensing circuit 40 senses, is also a current that corresponds to the set current If.

There may be provided, between the low potential terminal GND and each of the other terminals, a diode which protects an inside circuit or an outside apparatus of the driving circuit 100 from overvoltage. In the example of FIG. 1, a diode 26 is provided between the input terminal IN and the low potential terminal GND, a diode 28 is provided between the state terminal ST and the low potential terminal GND, a diode 30 is provided between the sense terminal SNS and the low potential terminal GND, and a diode 32 is provided between the high potential terminal Vcc and the low potential terminal GND. Also, there may be provided, between the high potential terminal Vcc and the gate terminal of the power device 12, a protection circuit 24. The protection circuit 24 may include two diodes arranged in series in an opposite direction. The driving circuit 100 may be provided with a current source 36 that supplies a constant current from the input terminal IN to the low potential terminal GND.

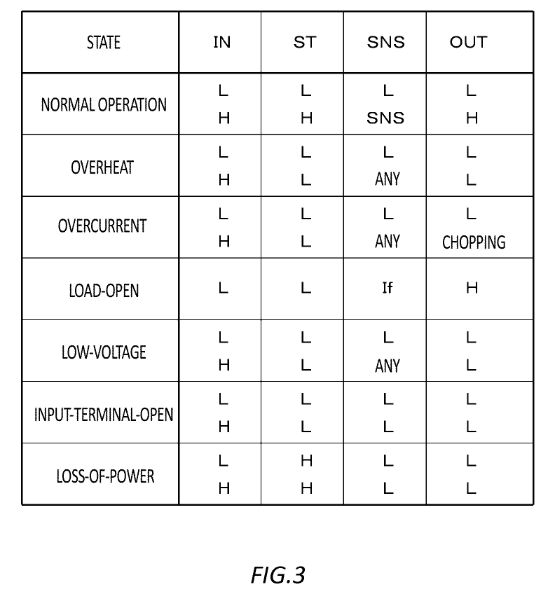

FIG. 3 illustrates an example of combinations of respective states of the driving circuit 100 and, logical values of the input signal IN, the state signal ST, the sensing signal SNS, and the output signal OUT. In the example of FIG. 3, there are shown, as states of the driving circuit 100, the normal operation state, the overheat state, the overcurrent state, the load-open state, the low-voltage state, the input-terminal-open state, and the loss-of-power state.

In the respective states, the input signal IN has a logical value pattern where H logic and L logic appear alternately. Note that in the load-open state, the management apparatus 300 may fix a logical value of the input signal IN to L logic.

In the normal state, where the first power source 210 is connected to the high potential terminal Vcc and no abnormal states are detected, the state-signal generation unit 34 outputs, as the state signal ST, a logical value which corresponds to the input signal IN. In the normal state, the control circuit 60 controls, when the input signal IN is L logic, the state-signal generation unit 34 to be in the ON state, to connect the state terminal ST to the low potential GND. In the normal state, the control circuit 60 controls, when the input signal IN is H logic, the state-signal generation unit 34 to be in the OFF state to disconnect the state terminal ST and the low potential GND. The state-signal generation unit 34 of the present example causes, in the normal state, the logical value of the state signal ST and the logical value of the input signal IN to match. The management apparatus 300 may determine, when the logical value of the state signal ST transitions corresponding to the input signal IN, that the driving circuit 100 is in the normal state. The management apparatus 300 may determine, when the logical value of the state signal ST does not transition corresponding to the input signal IN, that some abnormality is occurring at the driving circuit 100.

In the normal operation state, the sensing signal SNS indicates a value corresponding to the input signal IN. When the input signal IN is L logic, since the power device 12 is controlled to be in the OFF state, there is no current flowing through the power device 12. Thus, the sensing signal SNS is L logic. When the input signal IN is H logic, the output current Iout flows through the power device 12. Thus, the sensing signal SNS indicates the value SNS, which corresponds to the output current Iout. The value SNS may be H logic. The management apparatus 300 may determine, when the logical values of the state signal ST and the sensing signal SNS transition corresponding to the input signal IN, that the driving circuit 100 is in the normal state. The management apparatus 300 may determine, when the logical value of at least one of the state signal ST or the sensing signal SNS does not transition corresponding to the input signal IN, that some abnormality is occurring at the driving circuit 100.

The state-signal generation unit 34 of the present example outputs, in the load-open state, the second logical value (in the present example, L logic) as the state signal ST. In the load-open state, the control circuit 60 controls the state-signal generation unit 34 to be in the ON state to connect the state terminal ST to the low potential GND. While the load-open state continues, the logical value of the state signal ST is fixed to L logic. In the overheat state, the overcurrent state, the low-voltage state, and the input-terminal-open state, the state-signal generation unit 34 may also fix the logical value of the state signal ST to L logic. In these states, even when the logical value of the input signal IN transitions, the logical value of the state signal ST is fixed to L logic.

In the load-open state, the sensing signal SNS indicates a value corresponding to the set current If. The value corresponding to the set current If may be H logic. The control circuit 60 may control, in the load-open state, the MOSFET 52 to be in the ON state and control, when not in the load-open state, the MOSFET 52 to be in the OFF state. This control allows for discriminating, based on the sensing signal SNS, between the regular, OFF state, where the input signal IN indicates L logic in the normal operation state, and a state where the input signal IN indicates L logic in the load-open state. The management apparatus 300 may determine as the normal operation state, a state where when the input signal IN indicates L logic, the state signal ST indicates L logic and the sensing signal SNS indicates L logic. The management apparatus 300 may determine as the load-open state, when the input signal IN indicates L logic, a state where the state signal ST indicates L logic and the sensing signal SNS indicates H logic (or the set value If).

In the overheat state, the overcurrent state, the low-voltage state, and the input-terminal-open state, the control circuit 60 controls, when the input signal IN is L logic, the sensing signal SNS to be L logic. The control circuit 60 may control, when the input signal IN is L logic, the power device 12 to be in the OFF state. Thereby, the management apparatus 300 can discriminate between these abnormal states and the load-open state. In the overheat state, the overcurrent state, and the low-voltage state, the sensing signal SNS may indicate, when the input signal IN is H logic, any logical value. In the input-terminal-open state, the power device 12 is fixed in the OFF state, and the sensing signal SNS is fixed to L logic since the input signal IN is not input.

As described in FIG. 2, in the loss-of-power state where the first power source 210 is not connected to the high potential terminal Vcc, the state-signal generation unit 34 outputs the first logical value (in the present example, H logic) as the state signal ST. In the loss-of-power state, the control circuit 60 is not operating, and the state-signal generation unit 34 turns to the OFF state. Thus, while the loss-of-power state continues, the logical value of the state signal ST is fixed to H logic. That is, in the loss-of-power state, even when the logical value of the input signal IN transitions, the logical value of the state signal ST is fixed to H logic. The management apparatus 300 may determine, when the state signal ST is fixed to H logic regardless of the input signal IN, that the driving circuit 100 is in the loss-of-power state.

In the loss-of-power state, since the control circuit 60 is not operating, the power device 12 is controlled to be in the OFF state. Thus, the sensing signal SNS is fixed to L logic. As described above, the management apparatus 300 of the present example can identify, based on the state signal ST and the sensing signal SNS, each of the normal operation state, the load-open state, and the loss-of-power state. Note that when the loss-of-power state has been resolved and the power supply to the control circuit 60 has been resumed, the driving circuit 100 may automatically return to the normal operation state.

In the normal operation state, the output signal OUT indicates a logical value corresponding to the input signal IN. In the present example, the logical values of the input signal IN and the output signal OUT match. In the load-open state, since the load 200 is not connected to the output terminal OUT, a voltage of the output terminal OUT is fixed to H logic, which corresponds to the high potential Vcc. In the loss-of-power state, since the control circuit 60 and the driver 66 do not operate, the power device 12 is fixed in the OFF state. Thus, the output signal OUT is fixed to L logic (the low potential GND).

In the overheat state, the overcurrent state, the low-voltage state, and the input-terminal-open state, the control circuit 60 may fix the power device 12 to the OFF state. In this case, the output signal OUT in these abnormal states is fixed to L logic. Note that in the overcurrent state, during a period when the input signal IN should indicate H logic and cause the power device 12 to be ON, the control circuit 60 may cause the power device 12 to perform a chopping operation. The chopping operation is an operation in which the ON state and the OFF state alternately repeat. This allows for reducing the current flowing through the power device 12, and resolving the overcurrent state.

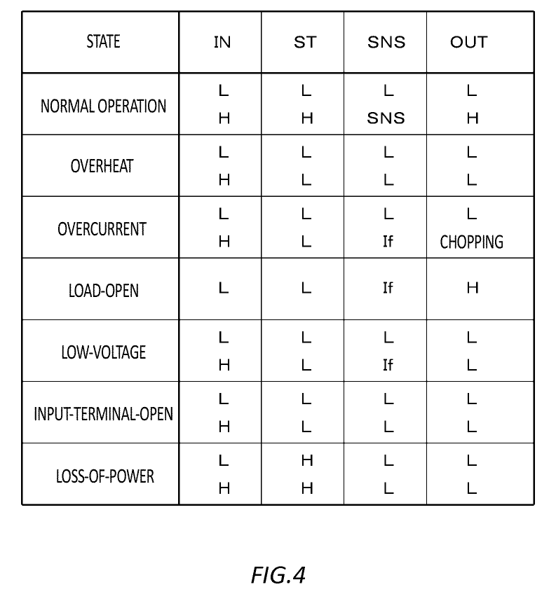

FIG. 4 illustrates another example of combinations of the respective states of the driving circuit 100 and, the logical values of the respective signals. In the present example, the logical values of the sensing signal SNS when the input signal IN indicates H logic in the overheat state, the overcurrent state, and the low-voltage state are different from those of the example of FIG. 3. The other logical values are the same as those of the example of FIG. 3.

The control circuit 60 of the present example controls, when the driving circuit 100 is in the overheat state, the power device 12 to be in the OFF state, regardless of the logical value of the input signal IN. Thereby, in the overheat state, the sensing signal SNS is fixed to L logic regardless of the logical value of the input signal IN.

The control circuit 60 of the present example controls, when the driving circuit 100 is in the overcurrent state and the input signal IN indicates a logical value with which the power device 12 is controlled to be in the ON state (H logic), the current flowing through the power device 12 to be at the set value If. Similarly, the control circuit 60 controls, when the driving circuit is in the low-voltage state and the input signal IN indicates a logical value with which the power device 12 is controlled to be in the ON state (H logic), the current flowing through the power device 12 to be at the set value If.

The present example allows for discriminating between the overheat state and other states based on the state signal ST and the sensing signal SNS. The management apparatus 300 may determine, when the state signal ST is fixed to L logic and the sensing signal SNS is fixed to L logic regardless of the logical value of the input signal IN, that the driving circuit 100 is in the overheat state.

The present example allows for identifying the overheat state of the driving circuit 100, to facilitate the protection of the driving circuit 100. For example, even in the overcurrent state, the disruption of the driving circuit 100 is often caused by an increased temperature occurring due to overcurrent. Thus, by protecting the driving circuit 100 in response to the overheat state, the driving circuit 100 can also be protected from overcurrent.

In another example, the sensing signal SNS when the input signal IN indicates H logic in the overcurrent state may be fixed to L logic. In this case, the sensing signal SNS when the input signal IN indicates H logic in the overheat state and the low-voltage state may be controlled to be at the set value If. This allows for identifying the overcurrent state.

In another example, the sensing signal SNS when the input signal IN indicates H logic in the low-voltage state may be fixed to L logic. In this case, the sensing signal SNS when the input signal IN indicates H logic in the overheat state and the overcurrent state may be controlled to be at the set value If. This allows for identifying the low-voltage state.

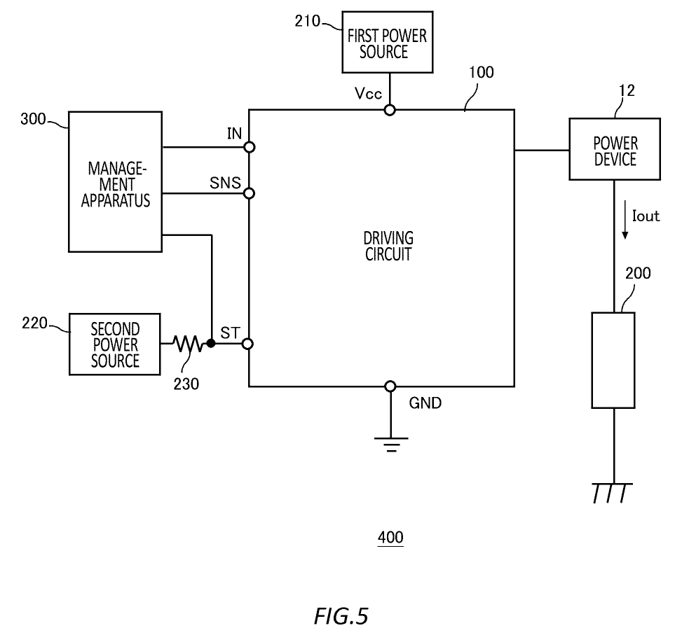

FIG. 5 illustrates another example of the power supply apparatus 400. In the present example, the power device 12 is provided outside the driving circuit 100. That is, the power device 12 is provided outside the semiconductor chip of the driving circuit 100. Other structures are the same as those of the examples described in FIGS. 1 to 4.

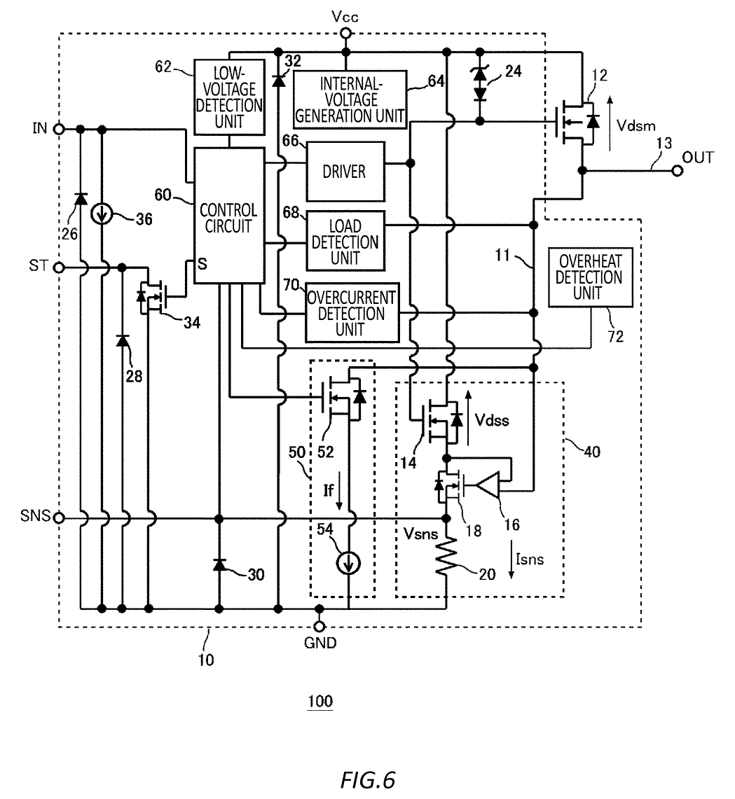

FIG. 6 illustrates another exemplary configuration of the driving circuit 100. In the present example, like the example of FIG. 5, the power device 12 is provided outside the driving circuit 100. The output terminal OUT and the output wiring 13 that are connected to the load may be provided outside the driving circuit 100, or may be provided inside the driving circuit 100. Other structures are the same as those of the examples described in FIGS. 1 to 4. In FIG. 6, a dashed line represents a boundary of the driving circuit 100.

While the present invention has been described by way of the embodiments, the technical scope of the present invention is not limited to the above-described embodiments. It is apparent to persons skilled in the art that various modifications or improvements can be made to the above-described embodiments. It is also apparent from the description of the claims that the embodiments to which such modifications or improvements are made may be included in the technical scope of the present invention.

What is claimed is:

1. A power supply apparatus comprising:
a driving circuit, including a power device, which drives the power device based on an input signal; and
a management apparatus which manages the driving circuit, wherein
the driving circuit includes
a state terminal which outputs a state signal indicating a state of the driving circuit;
a current-sensing terminal which outputs a sensing signal of a current flowing through the power device; and
a state-signal generation unit connected to the state terminal, which, in response to receiving driving power from a second power source different from a first power source connected to a high potential terminal of the driving circuit, generates the state signal, and
the management apparatus distinguishes individually, based on the state signal and the sensing signal, whether or not the state of the driving circuit is in a normal state where the power device has been turned OFF based on the input signal; whether or not the state of the driving circuit is in the loss-of-power state where there is no power supply from the first power source; and whether or not the state of the driving circuit is a load-open state where no load is connected to the power device.

2. The power supply apparatus according to claim 1, wherein
the driving circuit further includes;
a high potential terminal to which the first power source is connected; and
a control circuit which, in response to receiving source power from the first power source, controls the state-signal generation unit.

3. The power supply apparatus according to claim 2, wherein
the state-signal generation unit includes a transistor element having a drain terminal connected to the second power source and a gate terminal connected to the control circuit.

4. The power supply apparatus according to claim 3, wherein
the state-signal generation unit outputs, in a state where the first power source is not connected to the high potential terminal, a first logical value as the state signal; outputs, in a state where the first power source is connected to the high potential terminal, a logical value corresponding to the input signal as the state signal; and outputs, in the load-open state, a second logical value as the state signal.

5. The power supply apparatus according to claim 4, wherein
the driving circuit further includes a defined current unit which controls, in the load-open state, the current flowing through the power device to be at a set value that is set in advance.

6. The power supply apparatus according to claim 5, wherein
the power device is, in the state where the first power source is not connected to the high potential terminal, controlled to be in an OFF state.

7. The power supply apparatus according to claim 5, wherein
the control circuit controls, when the driving circuit is in an overheat state, the power device to be in an OFF state, and
the control circuit controls, when the driving circuit is in an overcurrent state and the input signal indicates a logical value with which the power device is controlled to be in an ON state, the current flowing through the power device to be at the set value.

8. The power supply apparatus according to claim 6, wherein
the control circuit controls, when the driving circuit is in an overheat state, the power device to be in an OFF state, and wherein
the control circuit controls, when the driving circuit is in an overcurrent state and the input signal indicates a logical value with which the power device is controlled to be in an ON state, the current flowing through the power device to be at the set value.

9. The power supply apparatus according to claim 7, wherein
the management apparatus further distinguishes, based on the state signal and the sensing signal, whether or not the state of the driving circuit is in the overheat state.

10. The power supply apparatus according to claim 8, wherein
the management apparatus further distinguishes, based on the state signal and the sensing signal, whether or not the state of the driving circuit is in the overheat state.

11. A management apparatus which manages a driving circuit, including a power device, which drives the power device based on an input signal, wherein
the driving circuit includes
a state terminal which outputs a state signal indicating a state of the driving circuit;
a current-sensing terminal which outputs a sensing signal of a current flowing through the power device; and
a state-signal generation unit connected to the state terminal, which, in response to receiving driving power from a second power source different from a first power source connected to a high potential terminal of the driving circuit, generates the state signal, and
the management apparatus distinguishes individually, based on the state signal and the sensing signal, whether or not the state of the driving circuit is in a normal state where the power device has been turned OFF based on the input signal; whether or not the state of the driving circuit is in the loss-of-power state where there is no power supply from the first power source; and whether or not the state of the driving circuit is in an load-open state where no load is connected to the power device.

12. The management apparatus according to claim 11, wherein
the management apparatus further distinguishes, based on the state signal and the sensing signal, whether or not the state of the driving circuit is in an overheat state.

13. A driving circuit which drives a power device based on an input signal, comprising:
a state terminal which outputs a state signal indicating a state of the driving circuit;
a current-sensing terminal which outputs a sensing signal of a current flowing through the power device; and
a defined current unit which switches whether or not to control the current flowing through the power device to be at a set value that is set in advance.

14. The driving circuit according to claim 13, wherein
the defined current unit controls, when the driving circuit is in a load-open state where no load is connected to the power device, the current flowing through the power device to be at the set value.

15. The driving circuit according to claim 13, further comprising:
a high potential terminal to which a first power source is connected;
a state-signal generation unit connected to the state terminal, which, based on receiving driving power from a second power source different from the first power source, generates the state signal; and
a control circuit which, in response to receiving source power from the first power source, controls the state-signal generation unit.

16. The driving circuit according to claim 15, wherein
the state-signal generation unit includes a transistor element having a drain terminal connected to the second power source and a gate terminal connected to the control circuit.

17. The driving circuit according to claim 16, wherein
the state-signal generation unit outputs, in a state where the first power source is not connected to the high potential terminal, a first logical value as the state signal; outputs, in a state where the first power source is connected to the high potential terminal, a logical value corresponding to the input signal as the state signal; and outputs, when the driving circuit is in a load-open state where no load is connected to the power device, a second logical value as the state signal.

18. The driving circuit according to claim 17, wherein
the power device is, in the state where the first power source is not connected to the high potential terminal, controlled to be in an OFF state.

19. The driving circuit according to claim 17, wherein
the control circuit controls, when the driving circuit is in an overheat state, the power device to be in an OFF state, and
the control circuit controls, when the driving circuit is in an overcurrent state and the input signal indicates a logical value with which the power device is controlled to be in an ON state, the current flowing through the power device to be at the set value.

20. The driving circuit according to claim 13, further comprising the power device.
